(19) United States
(12) Patent Application Publication
(10) Pub. No.: US 2016/0020758 A1
(43) Pub. Date: Jan. 21, 2016

(54) DELAY CONTROL SYSTEM HAVING TOLERANCE FOR PVT VARIATION

(71) Applicant: Samsung Electronics Co., Ltd., Gyeonggi-do (KR)

(72) Inventor: YOUNG-BOK KIM, Seoul (KR)

(21) Appl. No.: 14/710,248

(22) Filed: May 12, 2015

(30) Foreign Application Priority Data
Jul. 16, 2014 (KR) 10-2014-0090005

(51) Int. Cl. H03K 5/134

(52) U.S. Cl. CPC H03K 5/134; H03K 2005/00019

(57) ABSTRACT

A delay control system has a tolerance for process, voltage, and temperature (PVT) variations. The delay control system includes a detection compensation block configured to receive a constant current source, detect a PVT variation, and supply a compensation current; a current summation block configured to receive the compensation current and supply a summation current; a current-to-voltage converter configured to receive the summation current and supply a bias voltage depending on the amount of the summation current; and a delay chain block configured to adjust a delay time in response to the bias voltage. Related methods are also described.

### CROSS-REFERENCE TO RELATED APPLICATION

This application claims priority under 35 U.S.C. §119 to Korean Patent Application No. 10-2014-0090005 filed on Jul. 16, 2014, the disclosure of which is hereby incorporated by reference in its entirety.

### BACKGROUND

1. Field

Embodiments of the inventive concepts relate to delay control systems and methods.

2. Description of Related Art

A high-speed interface can be used to transfer high-speed data through a channel. In general, the high-speed interface may be used when RGB graphic data is transferred onto a panel of a digital television (DTV), a liquid-crystal display (LCD), or the like, or when large-capacity image data is transferred to a memory or a controller on a timing controller (TCON) chip. High-speed interfaces also may be used in other electronic circuit applications.

Such the high-speed interface may use the delay control system. Since a delay chain of the delay control system is sensitive to process, voltage, and temperature (PVT) variations, controlling the delay control system to be less sensitive with respect to the PVT variations and to maintain a constant delay time may be important factors to control the high-speed interface. Delay control systems also may be used in many other electronic circuit applications.

### SUMMARY

Embodiments of the inventive concepts can provide a delay control system having delay cells in which a delay time can be constantly maintained notwithstanding process, voltage, and temperature (PVT) variation.

The technical objectives of the inventive concepts are not limited to the above disclosure; other objectives may become apparent to those of ordinary skill in the art based on the following descriptions.

In accordance with an aspect of the inventive concepts, a delay control system includes a detection compensation block configured to receive a constant current source, detect a PVT variation and supply a compensation current; a current summation block configured to receive the compensation current, and supply a summation current; a currently-to-voltage (IV) converter configured to receive the summation current and supply bias voltages depending on the amount of the summation current, and a delay chain block configured to adjust a delay time in response to the bias voltages.

In an embodiment, the detection compensation block may include a power supply voltage (VDD) compensation unit and a threshold voltage compensation unit which supply a VDD compensation current and a threshold voltage compensation current, respectively.

In another embodiment, the VDD compensation unit is configured to receive the constant current source, detect a VDD variation, and supply the VDD compensation current from the constant current source in response to the VDD variation.

In still another embodiment, the VDD compensation unit is configured to supply the VDD compensation current smaller than a value when a detected VDD is higher than a voltage, and the VDD compensation current greater than the value when the detected VDD is lower than the voltage.

In yet another embodiment, the threshold voltage compensation unit is configured to receive the constant current source, detect a variation of a threshold voltage, and supply the threshold voltage compensation current from the constant current source in response to the variation of the threshold voltage.

In yet another embodiment, the threshold voltage compensation unit is configured to decrease the threshold voltage compensation current to be smaller than a value when the threshold voltage is detected to be lower than a voltage, and increase the threshold voltage compensation current to be greater than the value when the threshold voltage is detected higher than the voltage.

In yet another embodiment, the current summation block is configured to sum the VDD compensation current and the threshold voltage compensation current.

In yet another embodiment, the IV converter may include a PBIAS voltage that controls a plurality of PMOS transistors of the delay chain block and an NBIAS voltage that controls a plurality of NMOS transistors of the delay chain block, and the IV converter is configured to decrease a level of the PBIAS voltage and increase a level of the NBIAS voltage when the summation current is more than a value, and increase the level of the PBIAS voltage and decrease the level of the NBIAS voltage when the summation current is less than the value.

In yet another embodiment, the delay chain block may include a plurality of delay cells, and a response rate of each delay cell may be controlled by the PBIAS voltage and the NBIAS voltage.

In accordance with another aspect of the inventive concepts, a method of controlling a delay control system may include detecting a PVT variation and generating a VDD compensation current and a threshold voltage compensation current, generating a summation current including both the VDD compensation current and the threshold voltage compensation current, adjusting bias voltages for a delay chain block in response to the summation current, and adjusting a delay time by the bias voltages and driving the delay chain block.

In an embodiment, the generating of the VDD compensation current may include increasing the VDD compensation current increased to more than an amount when a VDD voltage is decreased to less than a voltage value, and the VDD compensation current decreased to less than the amount when the VDD voltage is increased to more than the voltage.

In another embodiment, the generating of the threshold voltage compensation current may include decreasing and supplying the threshold voltage compensation current when a threshold voltage is decreased to less than a value, and increasing and supplying the threshold voltage compensation current when the threshold voltage is increased to more than the value.

In still another embodiment, the generating of the summation current may further include supplying summation of a value increased by M times of the VDD compensation current and a value increased by N times of the threshold voltage compensation current.

In yet another embodiment, the adjusting of the bias voltages may include decreasing a bias voltage for a PMOS transistor and increasing a bias voltage for an NMOS transistor when the summation current increased to more than a value is received, and increasing the bias voltage for a PMOS transfer and decreasing the bias voltage for an NMOS transistor when the summation current decreased to less than the value is received.

In yet another embodiment, a response speed of the delay chain block may be decreased by increasing the bias voltage for a PMOS transistor and decreasing the bias voltage for an NMOS transistor, and increased by decreasing the bias voltage for a PMOS transistor and increasing the bias voltage for an NMOS transistor.

In yet other embodiments, a delay control system comprises a constant current source that is configured to provide a constant current; a power supply voltage compensation circuit that is powered by a power supply voltage and is configured to generate a power supply voltage compensation current from the constant current in response to variations of the power supply voltage; and a threshold voltage compensation circuit that is configured to generate a threshold voltage compensation current from the constant current in response to variations in a threshold voltage of a transistor in the threshold voltage compensation circuit. The delay control system further comprises a current combining circuit that is configured to generate a combined compensation current from the power supply voltage compensation current and the threshold voltage compensation current; a current-to-voltage converter that is configured to generate a transistor bias voltage from the combined compensation current; and a delay circuit that includes a plurality of transistors to which the transistor bias voltage is applied and that is configured to delay an input signal by an amount that is based on the transistor bias voltage that is applied to the plurality of transistors.

In some embodiments, the power supply voltage compensation circuit is configured to generate a first power supply compensation current in response to the power supply voltage being greater than a value and to generate a second power supply compensation current in response to the power supply voltage being less than the value. In other embodiments, the threshold voltage compensation circuit is configured to generate a first threshold voltage compensation current in response to the threshold voltage being greater than a value and to generate a second threshold voltage compensation current in response to the threshold voltage being less than the value. In yet other embodiments, the current combining circuit is configured to sum the power supply voltage compensation current and the threshold voltage compensation current. In still other embodiments, the current-to-voltage converter is configured to generate an NMOS transistor bias voltage and a PMOS transistor bias voltage from the combined compensation current. In yet other embodiments, the delay circuit includes a plurality of NMOS and PMOS transistors to which the respective NMOS transistor bias voltage and PMOS transistor bias voltage are applied and the delay circuit is configured to delay the input signal by an amount that is based on the NMOS transistor bias voltage that is applied to the plurality of NMOS transistors and on the PMOS transistor bias voltage that is applied to the plurality of PMOS transistors. The embodiments described in this paragraph may be combined in any and all combinations and subcombinations.

### BRIEF DESCRIPTION OF THE DRAWINGS

The foregoing and other features and potential advantages of the inventive concepts will be apparent from the more particular description of various embodiments of the inventive concepts, as illustrated in the accompanying drawings in which like reference characters refer to the same parts throughout the different views. The drawings are not necessarily to scale, emphasis instead being placed upon illustrating the principles of the inventive concepts. In the drawings:

FIGS. 1A and 1B, which may be collectively referred to herein as FIG. 1, are block diagrams showing a delay control system in accordance with embodiments of the inventive concepts;

FIG. 2 is a circuit diagram showing a VDD compensation unit shown in FIG. 1 in detail;

FIG. 3 is a circuit diagram showing a threshold voltage compensation unit shown in FIG. 1 in detail;

FIG. 4 is a circuit diagram showing a current summation block shown in FIG. 1 in detail;

FIG. 5 is a circuit diagram showing an IV converter shown in FIG. 1 in detail;

FIG. 6 is a circuit diagram showing a delay cell of a delay chain block shown in FIG. 1 in detail;

FIG. 7 is a flowchart showing a method of controlling the delay control system shown in FIG. 1;

FIG. 8 is a block diagram showing a computer system including the delay control system shown in FIG. 1 in accordance with an embodiment of the inventive concepts;

FIG. 9 is a block diagram showing a computer system including the delay control system shown in FIG. 1 in accordance with another embodiment of the inventive concepts; and

FIG. 10 is a block diagram showing a computer system including the delay control system shown in FIG. 1 in accordance with still another embodiment of the inventive concept.

### DETAILED DESCRIPTION OF THE EMBODIMENTS

Hereinafter, various embodiments of the inventive concepts will be described in detail with reference to the accompanying drawings. In detailed descriptions of the various embodiments of the inventive concepts, detailed descriptions of well-known configurations unrelated to the gist of the inventive concepts will be omitted. In this specification, when reference numerals are assigned to components of each drawing, it should be noted that, although the same components are illustrated in different drawings, the same numerals are assigned as much as possible.

Particular structural or functional descriptions for embodiments disclosed in this specification are only for the purpose of description of the embodiments of the inventive concepts. The embodiments of the inventive concepts may be various modifications in form and are not limited to the exemplary embodiments in this specification.

While the inventive concepts are susceptible to various modifications and alternative forms, specific embodiments thereof are shown by way of example in the drawings and will herein be described in detail. It should be understood, however, that there is no intent to limit the inventive concepts to the particular forms disclosed, but on the contrary, the inventive concepts are to cover all modifications, equivalents, and alternatives falling within the spirit and scope of the inventive concepts.

It will be understood that, although the terms “first,” “second,” etc. may be used herein to describe various elements, these elements should not be limited by these terms. These terms are only used to distinguish one element from another. For example, a first element could be termed a second element, and similarly, a second element could be termed a first element, without departing from the scope of the inventive concepts.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion, that is, “between” versus “directly between,” adjacent” versus “directly adjacent,” etc.

The terminology used herein is for the purpose of describing particular embodiments only and is not intended to be limiting of the present inventive concepts. As used herein, the singular forms “a,” “an,” and “the” are intended to include the plural forms as well, unless the context clearly indicates otherwise. It will be further understood that the terms “comprises,” “comprising,” “includes,” and/or “including” (and variants thereof) when used in this specification, specify the presence of stated features, steps, operations, elements, and/or components, but do not preclude the presence or addition of one or more other features, steps, operations, elements, components, and/or groups thereof.

Unless otherwise defined, all terms (including technical and scientific terms) used herein have the same meaning as commonly understood by one of ordinary skill in the art to which these inventive concepts belong. It will be further understood that terms, such as those defined in commonly used dictionaries, should be interpreted as having a meaning which is consistent with their meaning in the context of the relevant art and will not be interpreted in an idealized or overly formal sense unless expressly so defined herein.

Meanwhile, when an embodiment can be implemented differently, functions or operations described in a particular block may occur in a different way from a flow described in the flowchart. For example, two consecutive blocks may be performed simultaneously, or the blocks may be performed in reverse according to related functions or operations.

Hereinafter, various embodiments of the inventive concepts will be described in detail with reference to the accompanying drawings.

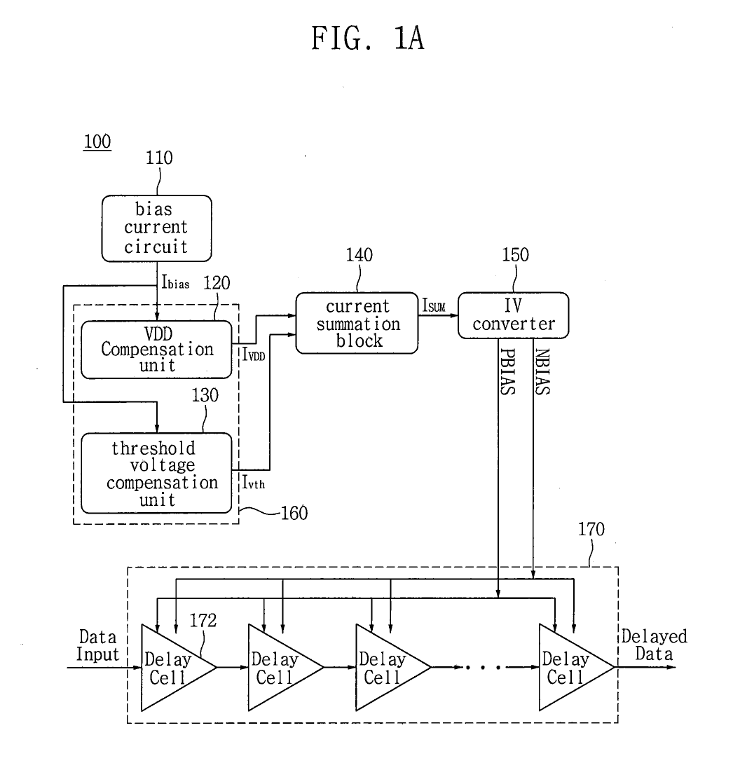

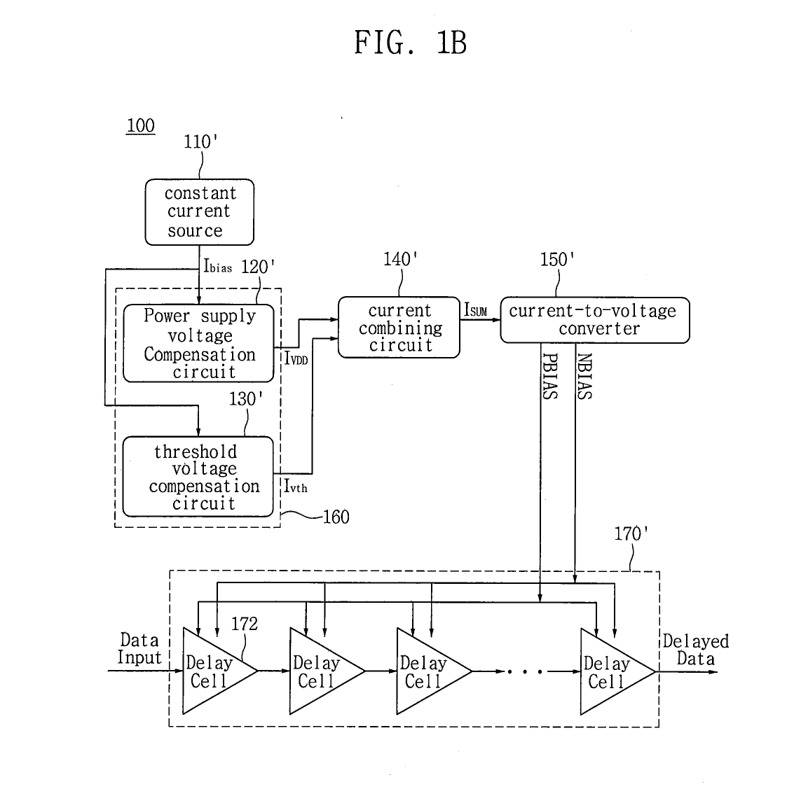

FIGS. 1A and 1B, which may be collectively referred to herein as FIG. 1, are block diagrams showing a delay control system in accordance with an embodiment of the inventive concepts.

Referring to FIG. 1A, a delay control system 100 in accordance with an embodiment of the inventive concepts includes a bias current circuit 110, a detection compensation block 160, a current summation block 140, an IV converter 150, and a delay chain block 170.

The bias current circuit 110 is a constant current source which supplies a current to the delay control system 100 and may supply a constant bias current I_{bias} to the detection compensation block 160.

The detection compensation block 160 in accordance with the embodiment of the inventive concepts includes a VDD compensation unit 120 and a threshold voltage compensation unit 130.

The VDD compensation unit 120 may receive a current from the bias current circuit 110, may detect a current state of VDD, and perform an appropriate compensation. That is, the VDD compensation unit 120 may compensate to decrease a VDD compensation current I_{VDD} when the detected VDD is higher than a voltage such as a preset voltage, and to increase the VDD compensation current I_{VDD} when the detected VDD is lower than the voltage.

The threshold voltage compensation unit 130 may receive a current from the bias current circuit 110, may detect a variation of a threshold voltage, and perform an appropriate compensation. That is, the threshold voltage compensation unit 130 may increase or decrease a threshold voltage compensation current Iᵥₜₕ according to whether a threshold voltage of a transistor in a circuit is increased or not. For example, the threshold voltage compensation unit 130 may increase the threshold voltage compensation current Iᵥₜₕ when the threshold voltage of the transistor is increased, and decrease the threshold voltage compensation current Iᵥₜₕ when the threshold voltage of the transistor is decreased.

According to the embodiment of the inventive concepts, a process, voltage, and temperature (PVT) variation is detected using the detection compensation block 160, an appropriate compensation current with respect to the variation is supplied, and thus, subsequent delay cells 172 of the delay chain block 170 may be operated to be less sensitive, and in some embodiments insensitive, with respect to the PVT variation.

The current summation block 140 may receive the VDD compensation current I_{VDD} and the threshold voltage compensation current Iᵥₜₕ from the detection compensation block 160, add both of the compensation currents, and supply a summation current I_{SUM} to the IV converter 150. Other combining operations instead of or in addition to summation also may be used.

The IV converter 150 may receive the summation current I_{SUM}, and appropriately adjust bias voltages required for the delay chain block 170, that is, PBIAS and NBIAS voltages, according to the amount of the summation current I_{SUM}. The IV converter 150 may decrease a level of the PBIAS voltage and increase a level of the NBIAS voltage when the amount of the summation current U_{SUM} is increased to more than a value, such as a preset value. In contrast, the IV converter 150 may increase the level of the PBIAS voltage and decrease the level of the NBIAS voltage when the amount of the summation current I_{SUM} is decreased to less than the value. That is, the IV converter 150 may appropriately adjust a PBIAS voltage which controls a predetermined number of PMOS transistors of the delay chain block 170 and an NBIAS voltage which controls a predetermined number of NMOS transistors of the delay chain block 170 according to the amount of the received summation current I_{SUM}, and thus reduce a delay variation.

The delay chain block 170 includes a plurality of delay cells 172. The plurality of delay cells 172 are connected with each other in series, and each delay cell is formed to have an equivalent delay time. In other embodiments, connections other than series connections also may be provided.

In the delay chain block 170, when data is input, the data may pass through a number n of delay cells and be delayed by the number of the delay cells, in other words, the amount of n*Δt, and then finally output as ‘delayed data’. Each of the delay cells 172 may be controlled by the PBIAS voltage and the NBIAS voltage. According to the embodiment of the inventive concepts, by a configuration as described above, the amount of the current may be detected and compensated according to the PVT variation, and thus, the PBIAS voltage and the NBIAS voltage may be appropriately compensated. Therefore, the delay variation of the delay cell 172 due to the PVT may be reduced or eliminated in the delay chain block 170. That is, a constant delay is maintained between the delay cells 172 even in the PVT variation, and thus overall operations of the circuit may be stably supported.

Referring to FIG. 1B, a delay control system according to other embodiments of the inventive concepts include a constant current source 110′ that is configured to provide a constant current I_{bias}. A power supply voltage compensation circuit 120′ is powered by a power supply voltage and is configured to generate a power supply voltage compensation current I_{VDD} from the constant current I_{bias} in response to variations of the power supply voltage. A threshold voltage compensation circuit 130′ is configured to generate a threshold voltage compensation current Iᵥₜₕ from the constant current I_{bias} in response to variations in a threshold voltage of a transistor in the threshold voltage compensation circuit 130′. A current combining circuit 140′ is configured to generate a combined compensation current I_{SUM} from the power supply voltage compensation current I_{VDD} and the threshold voltage compensation current Iᵥₜₕ. A current-to-voltage converter 150′ is configured to generate a transistor bias voltage PBIAS, NBIAS from the combined compensation current I_{SUM}. A delay circuit 170′ includes a plurality of transistors to which the transistor bias voltage PBIAS, NBIAS is applied and that is configured to delay an input signal by an amount that is based on the transistor bias voltage that is applied to the plurality of transistors.

Hereinafter, functions of the blocks each will be described in detail with reference to the next accompanying drawings.

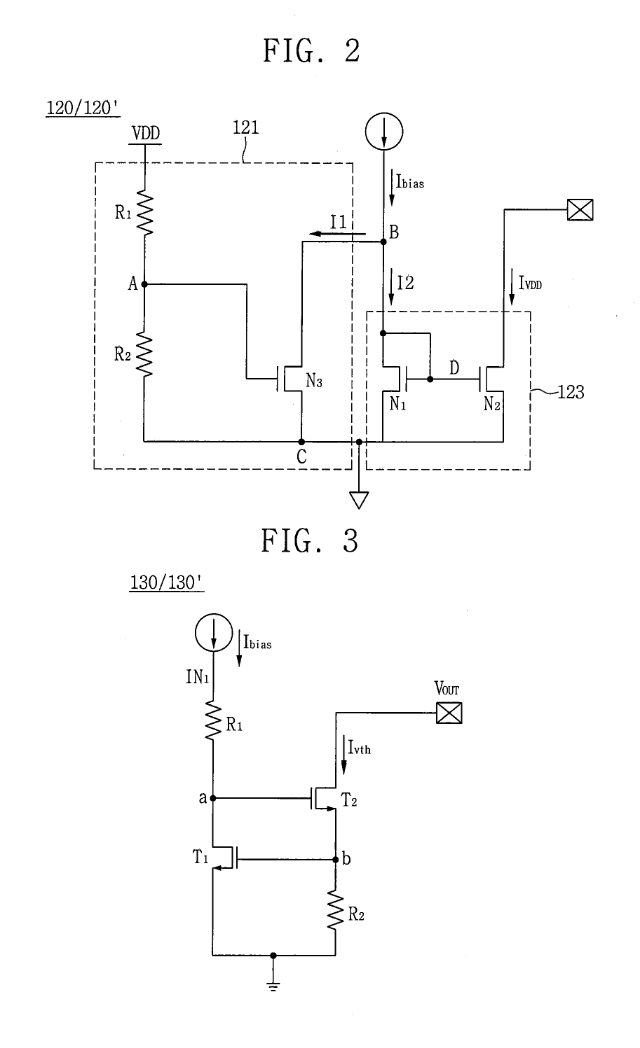

FIG. 2 is a circuit diagram showing the VDD compensation unit 120 or the power supply voltage compensation circuit 120′ shown in FIGS. 1A and 1B, respectively, in detail.

Referring to FIG. 2, the VDD compensation unit 120 or the power supply voltage compensation circuit 120′ includes a voltage detection part 121 and a current adjusting part 123.

First, the voltage detection part 121 may detect a variation of a VDD voltage.

Such the voltage detection part 121 includes a first resistor R₁, a second resistor R₂, and a third NMOS transistor N₃.

The first resistor R₁ and the second resistor R₂ may be provided to form both ends of a node A, respectively. A voltage of the node A is configured so that the VDD voltage is divided into a half of the VDD voltage by the first resistor R₁ and the second resistor R₂. To this end, the first resistor R₁ and the second resistor R₂ may be provided to have a substantially equivalent resistance.

The third NMOS transistor N₃ is provided between the node A and a node B. Specifically, a gate of the third NMOS transistor N₃ is connected to the node A, a source thereof is connected to a node C, and a drain thereof is connected to the node B. As such, the third NMOS transistor N₃ may be controlled by a voltage of the node A. When a current which flows through the third NMOS transistor N₃ is referred to as I1, the amount of I1 may be changed according to a variation of the voltage of the node A. Therefore, the voltage detection part 121 may detect a variation of the VDD voltage through the third NMOS transistor N₃.

The current adjusting part 123 includes a first NMOS transistor N₁ and a second NMOS transistor N₂.

The first NMOS transistor N₁ and the second NMOS transistor N₂ may be connected to each other to have a current mirror structure. The first NMOS transistor N₁ may be connected to a node D in a diode connection, and a gate of the second NMOS transistor N₂ may be connected to the node D. Thus, the amount of the current which flows through a path of the first NMOS transistor N₁ and the amount of the current which flows through a path of the second NMOS transistor N₂ may be the same. Here, the first and second NMOS transistors N₁ and N₂ may be provided so that sizes thereof are the same.

In this case, a bias current I_{bias} may be a summation of the current I1 which flows through a path of the third NMOS transistor N₃ and a current I2 which flows through the path of the first NMOS transistor N₁ as in the following Equation 1.

I_{bias}=I1+I2 [Equation 1]

(I_{bias} is a bias current, I1 is a current which flows through a path of a third NMOS transistor N₃, and I2 is a current which flows through a path of a first NMOS transistor N₁.)

When the amount of the current I1 which flows through the path of the third NMOS transistor N₃ is reduced, the amount of the current I2 which flows through the path of the first NMOS transistor N₁ may be increased based on Equation 1. In contrast, when the amount of the current I1 which flows through the path of the third NMOS transistor N₃ is increased, the amount of the current I2 which flows through the path of the first NMOS transistor N₁ may be reduced. Further, a VDD compensation current I_{VDD} which flows through the path of the second NMOS transistor N₂ having a mirror structure with the first NMOS transistor N₁ may be supplied to be increased or decreased in response to the amount of the current I2 which flows through the path of the first NMOS transistor N₁.

More specifically describing an operation of the VDD compensation unit 120 or the power supply compensation circuit 120′, the variation of the VDD voltage may be detected in the voltage detection part 121. The VDD voltage may be an external power source and fluctuation of the VDD may occur in a voltage environment. When the variation of the VDD voltage occurs, fluctuation of the VDD voltage may also occur in a preset voltage of the node A, for example, a half VOID voltage. Therefore, the amount of the current I1 which flows through the path of the third NMOS transistor N₃ controlled by the voltage of the node A may be changed. That is, the voltage detection part 121 may detect a variation of the voltage of the node A, which is the VDD voltage, using the third NMOS transistor N₃.

For example, when the voltage of the node A is decreased, the amount of the current I1 which flows through the path of the third NMOS transistor N₃ may be reduced.

The current I2 which flows through the first NMOS transistor N₁ of the current adjusting part 123 may flow to have the amount increased to more than a preset amount and to meet the bias current I_{bias} which is a constant current source according to above-described Equation 1. Thus, the VDD compensation current I_{VDD}, which flows through the path of the second NMOS transistor N₂ connected to the first NMOS transistor N₁ in a mirror structure, may be increased.

That is, when the VDD compensation unit 120 or the power supply voltage compensation circuit 120′ detects that the VDD voltage which is an external voltage is decreased, the VDD compensation current I_{VDD} increased to more than the preset amount may be supplied.

Meanwhile, when the voltage of the node A is increased, the amount of the current I1 which flows through the third NMOS transistor N₃ may be increased.

The current I2 which flows through the first NMOS transistor N₁ of the current adjusting part 123 may flow to have the amount decreased to less than the preset amount and to meet the bias current I_{bias} which is a constant current source according to above-described Equation 1. Thus, the VDD compensation current I_{VDD}, which flows through the path of the second NMOS transistor N₂ connected to the first NMOS transistor N₁ in a mirror structure, may be decreased.

That is, when the VDD compensation unit 120 or the power supply voltage compensation circuit 120′ detects that the VDD voltage which is an external voltage is increased, the VDD compensation current I_{VDD} decreased to less than the preset amount may be supplied.

Stated differently, the power supply voltage compensation circuit 120′ is configured to generate a first power supply compensation current in response to the power supply voltage being greater than a value and to generate a second power supply compensation current in response to the power supply voltage being less than the value.

As described above, the VDD compensation unit 120 may detect a variation of the voltage capable of affecting the delay cell 172 (see FIG. 1) later, and supply the appropriate VDD compensation current I_{VDD} with respect to the variation.

FIG. 3 is a circuit diagram showing the threshold voltage compensation unit or circuit 130 or 130′, respectively, shown in FIGS. 1A and 1B, respectively, in detail.

The threshold voltage compensation unit/circuit 130/130′ may detect a variation of a threshold voltage Vth, which is sensitive to a process status and a temperature, and supply the threshold voltage compensation current Iᵥₜₕ with respect to the variation.

Referring to FIG. 3, the threshold voltage compensation unit/circuit 130/130′ includes a first resistor R₁, a second resistor R₂, a first NMOS transistor T₁, and a second NMOS transistor T₂.

A side of the first resistor R1 may be connected to a constant current source (a bias current I_{bias}), and the other side thereof may be connected to a node a.

A gate of the first NMOS transistor T₁ may be connected to a node b, a drain thereof may be connected to the node a, and a source thereof may be connected to a ground power source.

A gate of the second NMOS transistor T₂ may be connected to the node a, a drain thereof may be connected to an output node V_{OUT}, and a source thereof may be connected to the node b.

A side of the second resistor R₂ may be connected to the node b, and the other side thereof may be connected to the ground power source.

An operation of the threshold voltage compensation unit/circuit 130/130′ will be described in more detail.

First, the first and second NMOS transistors T₁ and T₂ may be provided to be always turned on and to be saturated.

The operation of the threshold voltage compensation unit 130 may detect whether threshold voltages of the first and second NMOS transistors T₁ and T₂ are changed or not, and supply the threshold voltage compensation current Iᵥₜₕ, when the bias current I_{bias} flows through the first resistor R₁ and the first NMOS transistor T₁ is provided to be always saturated.

A correlation between a voltage of the node b and the threshold voltages of the first and second NMOS transistors T₁ and T₂ may be represented as the following Equation 2.

$${I}_{OUT} = \frac{{V}_{GS 1}}{{R}_{2}} = \frac{{V}_{t} + {V}_{ov 1}}{{R}_{2}} = \frac{{V}_{t} + \sqrt{\frac{2 {l}_{IN}}{{{k}^{′} ( W / L )}_{1}}}}{{R}_{2}} \qquad [ Equation 2 ]$$

(V_{GS1} is a gate-source voltage of the first NMOS transistor, Vₒᵥ₁ is a drain-source voltage V_{DS} at a time in which the first NMOS transistor is saturated, k′ is a technical constant, W is a width of the first NMOS transistor, L is a length of the first NMOS transistor, and IN is an input voltage.)

That is, the voltage of the node b may be a voltage which may turn on the first NMOS transistor T₁, and at the same time a voltage supplied to the second resistor R₂.

Further, in Equation 2, the threshold voltage compensation current Iᵥₜₕ which is represented as a current Iₒᵤₜ which flows through the output node V_{OUT} may be represented as a current which flows through the second resistor R₂ and the node b.

As described above, when it is premised that the first NMOS transistor T₁ is turned on and saturated, in consideration of a turn-on condition of the first NMOS transistor T₁, a relationship in which a gate-source voltage I_{GS1} of the first NMOS transistor T₁ and the voltage of the node b are the same may be established. Thus, as shown in Equation 2, the threshold voltage compensation current Iᵥₜₕ may be represented using the second resistor R₂ and the gate-source voltage V_{GS2} of the first NMOS transistor T₁. In this case, the gate-source voltage V_{GS1} of the first NMOS transistor T₁ may be represented using a drain-source voltage V_{DS} at a time in which the first NMOS transistor T₁ is saturated, that is, a Vₒᵥ₁ of the first NMOS transistor T₁.

The above-mentioned process may be described by Equation 3.

V_{GS}−Vₜ=V_{DS} [Equation 3]

(V_{GS} is a gate-source voltage, V_{DS} is a drain-source voltage, and Vₜ is a threshold voltage.)

Meanwhile, the Vₒᵥ₁, which is a V_{DS} saturation voltage, is determined by the V_{GS} and threshold voltage Vₜ in a saturated status as shown in Equation 2.

Therefore, the threshold voltage compensation current Iᵥₜₕ which flows through the output node V_{OGT} may be represented as a function of Vₜ.

Thus, the threshold voltage compensation unit/circuit 130/130′ in accordance with the embodiment of the inventive concepts may detect a variation of the threshold voltage according to a process status and a temperature, and supply a compensation current with respect to the variation. In other words, in the threshold voltage compensation unit/circuit 130/130′, when the threshold voltage is changed, the gate-source voltage V_{GS} of the first NMOS transistor T₁ may be changed, and the amount of the current which flows through the output node V_{OUT} may be changed.

For example, when the threshold voltage is decreased according to the process status, the voltage of the node b is also decreased. Therefore, the threshold voltage compensation current Iᵥₜₕ which is a current Iₒᵤₜ of the output node V_{OUT} may be decreased and supplied according to Equation 2.

In contrast, when the threshold voltage is increased according to the process status, the voltage of the node b is also increased. Therefore, the threshold voltage compensation current Iᵥₜₕ which is a current Iₒᵤₜ of the output node may be increased and supplied according to Equation 2.

In other words, since the threshold voltage compensation unit/circuit 130/130′ in accordance with the embodiment of the inventive concepts detects a change of a condition in which an operational speed of the delay cell may be increased when the threshold voltage is decreased, the threshold voltage compensation unit/circuit 130/130′ further decreases the threshold voltage compensation current Iᵥₜₕ. Thus, the threshold voltage compensation unit/circuit 130/130′ controls to substantially further decrease the operational speed of the delay cell. Further, since the threshold voltage compensation unit/circuit 130/130′ detects that a change of a condition in which the operational speed of the delay cell may be decreased when the threshold voltage is increased, the threshold voltage compensation unit/circuit 130/130′ further increases the threshold voltage compensation current Ivth. Thus, the threshold voltage compensation unit/circuit 130/130′ may control to further increase the operational speed of the subsequent delay cell.

Stated differently, the threshold voltage compensation unit/circuit 130/130′ is configured to generate a first threshold voltage compensation current in response to the threshold voltage being greater than a value and generate a second threshold voltage compensation current in response to the threshold voltage being less than the value.

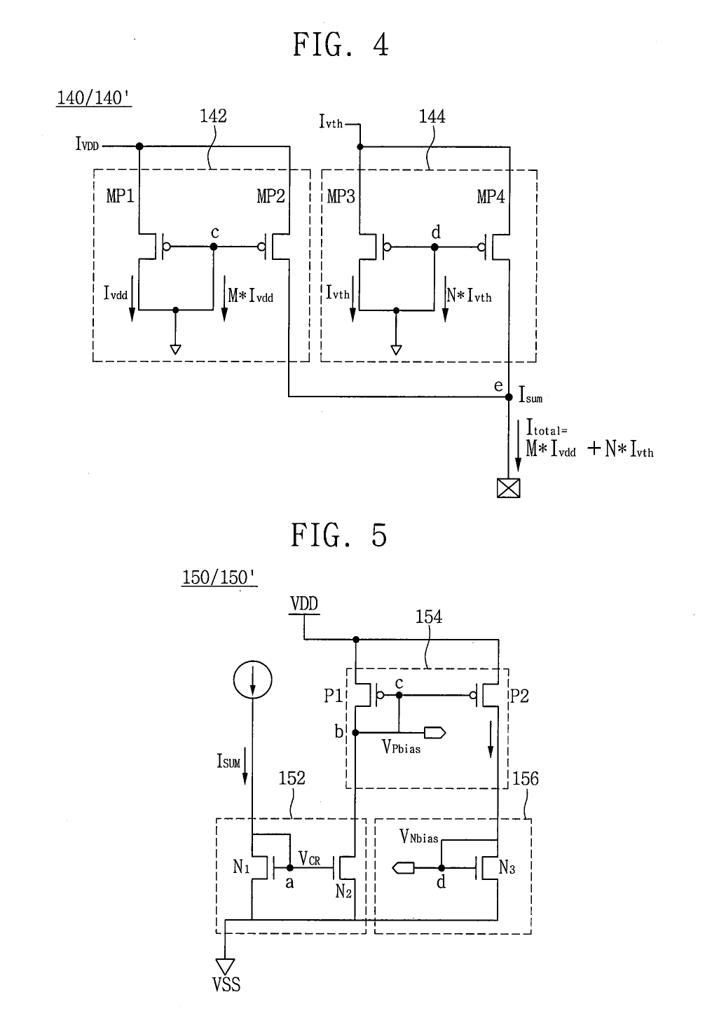

FIG. 4 is a circuit diagram showing the current summation block/combining circuit 140/140′ shown in FIGS. 1A and 1B, respectively, in detail.

Referring to FIG. 4, the current summation block/combining circuit 140/140′ includes a VDD compensation current receiver 142 and a threshold voltage compensation current receiver 144.

The current summation block/combining circuit 140/140′ in accordance with the embodiment of the inventive concepts may add the VDD compensation current increased by M times by the VDD compensation current receiver 142 and the threshold voltage compensation current increased by N times by the threshold voltage compensation current receiver 144, and supply the summation as a summation current I_{SUM}.

First, the VDD compensation current receiver 142 includes a first PMOS transistor MP1 and a second PMOS transistor MP2. Here, the second PMOS transistor MP2 may be provided to have a size greater than the first PMOS transistor MP1 by M times. Further, the first PMOS transistor MP1 and the second PMOS transistor MP2 may be connected to each other to have a current mirror structure. A gate of the first PMOS transistor MP1 may be connected to a node c, a source thereof may receive the VDD compensation current I_{VDD}, and a drain thereof may be connected to the node c in a diode connection. A gate of the second PMOS transistor MP2 may be connected to the node c, a source thereof may receive the VDD compensation current I_{VDD}, and a drain thereof may be connected to an output node e. Therefore, when the VDD compensation current I_{VDD} generated from the VDD compensation unit/circuit 120/120′ (see FIG. 2) is applied to the VDD compensation current receiver 142, a current corresponding to the amount of the received current may be output by a function of a current mirror circuit. However, here, as described above, as the second PMOS transistor MP2 is provided to have a size greater than the first PMOS transistor MP1 by M times, the VDD compensation current M*I_{VDD} having an amount increased by M times may be output when the VDD compensation current I_{VDD} is received.

The threshold voltage compensation current receiver 144 includes a third PMOS transistor MP3 and a fourth PMOS transistor MP4. Here, the fourth PMOS transistor MP4 may be provided to have a size greater than the third PMOS transistor MP3 by N times. Further, the third PMOS transistor MP3 and the fourth PMOS transistor MP4 may be connected to each other to have a current mirror structure. A gate of the third PMOS transistor MP3 may be connected to a node d, a source thereof may receive the threshold voltage compensation current Iᵥₜₕ, and a drain thereof may be connected to the node d in a diode connection. A gate of the fourth PMOS transistor MP4 may be connected to the node d, a source thereof may be connected to a VDD power, and a drain thereof may be connected to the output node e. Therefore, when the threshold voltage compensation current Iᵥₜₕ is applied to the threshold voltage compensation current receiver 144, a current corresponding to the amount of the received current may be output by the function of the current mirror circuit. However, here, as the fourth PMOS transistor MP4 is formed to have a size greater than the third PMOS transistor MP3 by N times, the threshold voltage compensation current N*Iᵥₜₕ having an amount increased by N times may be output when the threshold voltage compensation current Iᵥₜₕ is applied.

Thus, a current which flows through the output node e, that is, the summation current may flow to have substantially the same amount as a total amount of current which flow through the second PMOS transistor MP2 and the fourth PMOS transistor MP4.

In the embodiment of the inventive concepts, the VDD compensation current increased by M times and the threshold voltage compensation current increased by N times are described as examples. However, the compensation currents are not limited thereto, and it is possible to flexibly control the compensation currents without limit according to an intention of a designer. However, in the embodiment of the inventive concepts, when the PVT variation is detected and the compensation current with respect to the variation is supplied, a substantial example capable of supplying the appropriate amount of current is disclosed considering a configuration of the delay cells and a size of a circuit to be driven. Therefore, the scope of the inventive concepts may not be limited to the amounts of the currents of M times and N times.

Thus, the current summation block/combining circuit 140/140′ in accordance with the embodiment of the inventive concepts may supply a summation, which adds the VDD compensation current increased by M times and the threshold voltage compensation current increased by N times, as a summation current I_{SUM} in response to the detected the variation of the VDD voltage or the variation of the threshold voltage according to the temperature variation.

Stated differently, the current summation circuit/combining circuit 140/140′ is configured to sum the power supply voltage compensation current and the threshold voltage compensation current.

FIG. 5 is a circuit diagram showing the IV converter 150/150′ shown in FIGS. 1A and 1B, respectively, in detail.

The IV converter 150/150′ may receive the summation current I_{SUM} and optimize bias voltages for the delay chain block 170, that is PBIAS and NBIAS voltages according to the amount of the summation current I_{SUM}.

Referring to FIG. 5, the IV converter 150/150′ includes a current receiver 152, a PBIAS controller 154, and an NBIAS controller 156.

The current receiver 152 receives the summation current I_{SUM}.

The current receiver 152 includes a first NMOS transistor N₁ and a second NMOS transistor N₂. The first and second NMOS transistors N₁ and N₂ may be provided as transistors to have substantially the same size. A drain and a gate of the first NMOS transistor N₁ are connected in a diode connection, the gate thereof is connected to a node a, and a source thereof is connected to a ground power source VSS. The second NMOS transistor N₂ is connected to the first NMOS transistor N₁ to have a complementary structure, and connected to the first NMOS transistor N₁ to have a current mirror structure. Therefore, a current which flows through the second NMOS transistor N₂ may be controlled by mirroring with respect to a current which flows through the first NMOS transistor N₁.

The PBIAS controller 154 may control a PBIAS voltage in response to the summation current I_{SUM}.

The PBIAS controller 154 may include a first PMOS transistor P1 and a second PMOS transistor P2. The first and second PMOS transistors P1 and P2 may be provided as transistors to have substantially the same size. A drain and a gate of the first PMOS transistor P1 are connected in a diode connection, the drain and the gate thereof are connected to the node b and the node c, respectively, and a source thereof is connected to an external power source VDD. The first PMOS transistor P1 may provide the PBIAS voltage as an output voltage through the output node b. The second PMOS transistor P2 is connected to the first PMOS transistor P1 to have a complementary structure, and connected to the first PMOS transistor P1 to have a current mirror structure. Therefore, a current which flows through the second PMOS transistor P2 may be controlled by mirroring with respect to a current which flows through the first PMOS transistor P1.

The NBIAS controller 156 may control an NBIAS voltage in response to the PBIAS controller 154.

The NBIAS controller 156 includes a third NMOS transistor N₃. A gate and a drain of the third NMOS transistor N₃ are commonly connected to the node d in a diode connection, and a source thereof is connected to the ground power source VSS. The third NMOS transistor N₃ is connected to the second PMOS transistor P2 in series. The gate and the drain of the third NMOS transistor N₃ may be connected to the output node d and may provide the PBIAS voltage.

An operation of the IV converter 150/150′ will be described.

The IV converter 150/150′ in accordance with the embodiment of the inventive concepts may decrease the PBIAS voltage and increase the NBIAS voltage when the summation current I_{SUM} is increased in response to the summation current I_{SUM}, and output the voltages. Further, the IV converter 150/150′ may decrease the NBIAS voltage and increase the PBIAS voltage when the summation current I_{SUM} is decreased in response to the summation current I_{SUM}, and output the voltages.

That is, in the IV converter 150/150′, since drivability of the second NMOS transistor N₂ is further increased when the current receiver 152 receives the summation current I_{SUM} increased to more than a preset value, more current flows. Thus, the output node b connected to the drain of the second NMOS transistor N₂, that is, the PBIAS voltage, is decreased to less than the value. Therefore, the PBIAS controller 154 may provide the further decreased PBIAS voltage. Meanwhile, since the second PMOS transistor P2 is turned on by a gate voltage smaller than a preset value when the second PMOS transistor P2 is turned on by the node c connected to the output node b, drivability of the second PMOS transistor P2 may be further increased. Thus, a current greater than before may flow through the second PMOS transistor P2. A turn-on voltage of the gate of the third NMOS transistor N₃ connected to the second PMOS transistor P2 may also be increased. Therefore, the NBIAS voltage of the output node d may be increased and provided.

It may also be described conversely.

For example, in the IV converter 150/150′, when the current receiver 152 receives the summation current I_{SUM} decreased to less than the value, less current flows through the second NMOS transistor N₂. Thus, drivability of the second NMOS transistor N₂ is further reduced. Since the output node b that is, the PBIAS voltage, is increased to more than the value, the PBIAS controller 154 may provide the further increased PBIAS voltage. Meanwhile, as the second PMOS transistor P2 is turned on by a gate voltage greater than the value when the second PMOS transistor P2 is turned on by the node c connected to the output node b, a current less than before may flow through the second PMOS transistor P2. Therefore, a turn-on voltage of the gate of the third NMOS transistor N₃ connected to the second PMOS transistor P2 may also be increased, and thus, the NBIAS voltage of the output node d may be decreased and provided.

In other words, according to the embodiment of the inventive concepts, a delay may be adjusted so as to apply to a bias voltage which adjusts a delay of the actual delay cell using the summation current I_{SUM} which is a compensation current considered detection of the PVT variation.

As described above, since the large summation current I_{SUM} is shown with a compensation considered an increase in the threshold voltage or a decrease in the external voltage, the bias voltage may be adjusted to compensate with respect to the increase of the delay of the delay cell. That is, as it is adjusted so that the PBIAS voltage of the delay cell is further decreased and the NBIAS voltage thereof is further increased for a faster operation by detecting that the delay of the delay cell is increased, a delay factor of the delay cell may be removed.

Likewise, since the small summation current I_{SUM} is shown with a compensation considered a decrease in the threshold voltage or an increase in the external voltage, the bias voltage may be adjusted to compensate with respect to the decrease of the delay of the delay cell. That is, as it is adjusted so that the PBIAS voltage of the delay cell is further increased and the NBIAS voltage thereof is further decreased for a slower operation by detecting that the delay of the delay cell is decreased—a reduction factor of the delay may be removed.

The above-mentioned process may be simply summarized in Table 1 below.

TABLE 1

| | | Compensation | |
|---|---|---|---|
| Detection | Determination | Phase 1 | Compensation Phase 2 |
| Vth | SLOW | Compensate in a | Compensate in a FAST |
| Increase | | FAST condition | condition |
| or VDD | | Increase I_{SUM} | Delay decrease direction |
| Decrease | | | (PBIAS lower, |
| | | | NBIAS higher) |
| Vth | FAST | Compensate in a | Compensate in a SLOW |
| Decrease | | SLOW condition | condition |
| or VDD | | Decrease I_{SUM} | Delay increase direction |
| Increase | | | (PBIAS higher, |
| | | | NBIAS lower) |

As described above, according to the embodiment of the inventive concepts, the variations of the external voltage and the threshold voltage are detected and appropriately compensated with respect to the variations, and thus, the delay of the delay cell may be constantly maintained and stability of the operation may be improved.

Stated differently, the current-to-voltage converter 150/150∝ is configured to generate a transistor bias voltage from the combined compensation current. More specifically, the current-to-voltage converter 150/150′ is configured to generate an NMOS transistor bias voltage and a PMOS transistor bias voltage from the combined compensation current. Even more specifically, the delay circuit includes a plurality of NMOS and PMOS transistors to which the respective NMOS transistor bias voltage and PMOS transistor bias voltage are applied and the delay circuit is configured to delay the input signal by an amount that is based on the NMOS transistor bias voltage that is applied to the plurality of NMOS transistors and on the PMOS transistor bias voltage that is applied to the plurality of PMOS transistors.

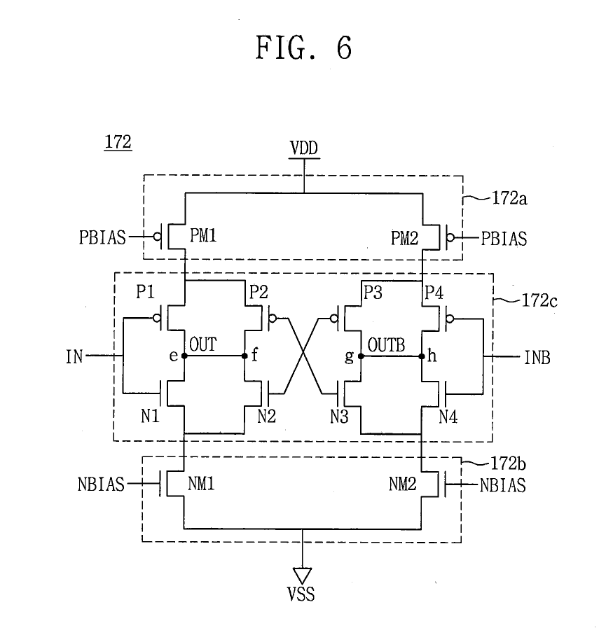

The following FIG. 6 is a circuit diagram showing the delay cell 172 of the delay chain block/circuit 170/170′ shown in FIG. 1 in detail.

Referring to FIG. 6, the delay cell 172 is similar to a general structure of the current starved delay cell, however, the applying of the bias voltage newly adjusted according to the impact of the external power source or the threshold voltage is different. Therefore, in the delay cell 172 in accordance with the embodiment of the inventive concepts, the PVT variation may be detected and then the amount of the delay may be determined by the compensated bias voltage.

The delay cell 172 includes a first bias adjusting part 172a, a second bias adjusting part 172b, and an inverter 172c.

The first bias adjusting part 172a may adjust an operational speed of a predetermined number of PMOS transistors of the inverter 172c.

Such the first bias adjusting part 172a includes a first PMOS transistor PM1 and a second PMOS transistor PM2.

A gate of the first PMOS transistor PM1 receives the PBIAS voltage, a source thereof is connected to a power voltage VDD, and a drain thereof is connected to the inverter 172c. A gate of the second PMOS transistor PM2 receives the PBIAS voltage, a source thereof is connected to the power voltage VDD, and a drain thereof is connected to the inverter 172c.

Continuously, the second bias adjusting part 172b may adjust operational speeds of a predetermined number of NMOS transistors of the inverter 172c.

Such the second bias adjusting part 172b includes a first NMOS transistor NM1 and a second NMOS transistor NM2.

A gate of the first NMOS transistor NM1 receives the NBIAS voltage, a source thereof is connected to a ground power source VSS, and a drain thereof is connected to the inverter 172c. A gate of the second NMOS transistor NM2 receives the NBIAS voltage, a source thereof is connected to the ground power source VSS, and a drain thereof is connected to the inverter 172c.

A circuit having a differential inverter may be applied to the inverter 172c.

The inverter 172c may receive input signals IN and TNB, which are inverted to each other, and provide output signals OUT and OUTB delayed according to the input signals by a predetermined time.

The inverter 172c includes a plurality of PMOS transistors P1, P2, P3, and P4, and a plurality of NMOS transistors N1, N2, N3, and N4.

The first PMOS transistor P1 and the first NMOS transistor N1 of the inverter 172c may be connected to each other in an inverter type. Thus, gates of the first PMOS transistor P1 and the first NMOS transistor Ni may commonly receive the input signal IN, and may provide the output signal OUT through a common node e in response to the input signal IN.

In contrast, the fourth PMOS transistor P4 and the fourth NMOS transistor N4 of the inverter 172c may also be connected to each other in an inverter type. Thus, gates of the fourth PMOS transistor P4 and the fourth NMOS transistor N4 may commonly receive the inverted input signal INB having an inverted level of the input signal IN, and may provide the inverted output signal OUTB through a common node h in response to the inverted input signal INB.

Meanwhile, the second PMOS transistor P2 and the second NMOS transistor N2 may be connected in series, and the third PMOS transistor P3 and the third NMOS transistor N3 may be connected in series. Here, gates of the second PMOS transistor P2 and the third NMOS transistor N3 may be cross-connected, and the gates of the third PMOS transistor P3 and the second NMOS transistor N2 may be cross-connected. A common node f of the second PMOS transistor P2 and the second NMOS transistor N2 which are connected in series is connected to the common node e of the first PMOS transistor P1 and the first NMOS transistor N1. A common node g of the third PMOS transistor P3 and the third NMOS transistor N3 may be connected to the common node h of the fourth PMOS transistor P4 and the fourth NMOS transistor N4.

An operation of the delay cell 172 in accordance of the embodiment of the inventive concepts will be described.

First, whether the first PMOS transistor, the first NMOS transistor, the fourth PMOS transistor, and the fourth NMOS transistor P1, N1, P4, and N4 are turned on or not may be determined in response to the input signal IN and the inverted input signal INB.

More specifically, when the input signal IN is a high level and the inverted input signal INB is a low level, the first NMOS transistor N1 and the fourth PMOS transistor P4 may be turned on, respectively, in response to the signals. Thus, the node e is decreased to have a low level by the operations of the first NMOS transistor N1 and the first NMOS transistor NM1 of the second bias adjusting part 172b, and thus, the output signal OUT of a high level invert of the input signal IN may be delayed and provided by a predetermined time. At this time, the NBIAS voltage applied to the first NMOS transistor NM1 of the second bias adjusting part 172b may be provided as a voltage already compensated according to the PVT variation. Therefore, when drivability of the first NMOS transistor NM1 is changed, a response speed of the first NMOS transistor N1 of the inverter 172c may be adjusted.

In the delay cell 172, the response speed of the output signal OUT provided in response to the input signal IN is preset in consideration of the delay time according to the intention of the designer. However, the operational speed of the first NMOS transistor N1 may be adjusted using the NBIAS voltage to reduce an impact by the PVT variation as described in the embodiment of the inventive concepts. Therefore, the delay time of the delay cell 172 may be adjusted according to the newly adjusted NBIAS voltage.

In contrast, when the input signal IN is a low level and the inverted input signal INB is a high level, the first PMOS transistor P1 and the fourth NMOS transistor N4 may be turned on, respectively, in response to the signals. Thus, the node e is increased to a high level by operations of the first PMOS transistor P1 and the first PMOS transistor PM1 of the first bias adjusting part 172a, the output signal OUT of a high level invert of the input signal IN may be delayed and provided by a predetermined time. At this time, the PBIAS voltage applied to the first PMOS transistor PM1 of the first bias adjusting part 172a may be provided as a voltage already compensated according to the PVT variation. Therefore, while drivability of the first PMOS transistor PM1 is changed, a response speed of the first PMOS transistor P1 of the inverter 172c may be adjusted.

That is, it is assumed that there is a condition in which it is operated to more increase the delay time than by any impact according to the VDD variation or the Vth variation (i.e. a condition in which the delay cell may be more slowly operated than expected). To this end, in the embodiment of the inventive concepts, the PBIAS voltage is adjusted to have a lower level, the NBIAS voltage is adjusted to have a higher level, and thus, a driving speed of the delay cell 172 may be substantially improved. Therefore, since the delay time is not added even in the external PVT variation, a variation of the delay time according to an external environment may be reduced.

Although the descriptions are repeated, it is assumed that there is a condition in which it is operated to more reduce the delay time than by any impact according to the VDD variation or the Vth variation (i.e. a condition in which the delay cell may be operated faster than expected). To this end, in the embodiment of the inventive concepts, the PBIAS voltage is adjusted to have a higher level, the NBIAS voltage is adjusted to have a lower level, and thus, a driving speed of the delay cell 172 may be substantially reduced. Therefore, since the delay time is not added even in the external PVT variation, the variation of the delay time according to the external environment may be reduced.

Meanwhile, since the second PMOS transistor P2, the second NMOS transistor N2, the third PMOS transistor P3, and the third NMOS transistor N3 are not operated according to the input signal IN, a leakage path of the signal may be blocked and thus, stability of the operation may be improved.

In the embodiment of the inventive concepts, although the circuit having a different inverter in which a swing width of the output signal is further reduced is illustrated, it is only for example and the scope of the inventive concepts is not limited thereto.

When a circuit part which receives the bias voltage as a compensated voltage is configured among the delay cells, which may be delayed by a predetermined time in response to the input signal IN and may provide the output signal OUT, it does not depart from the embodiment of the inventive concepts.

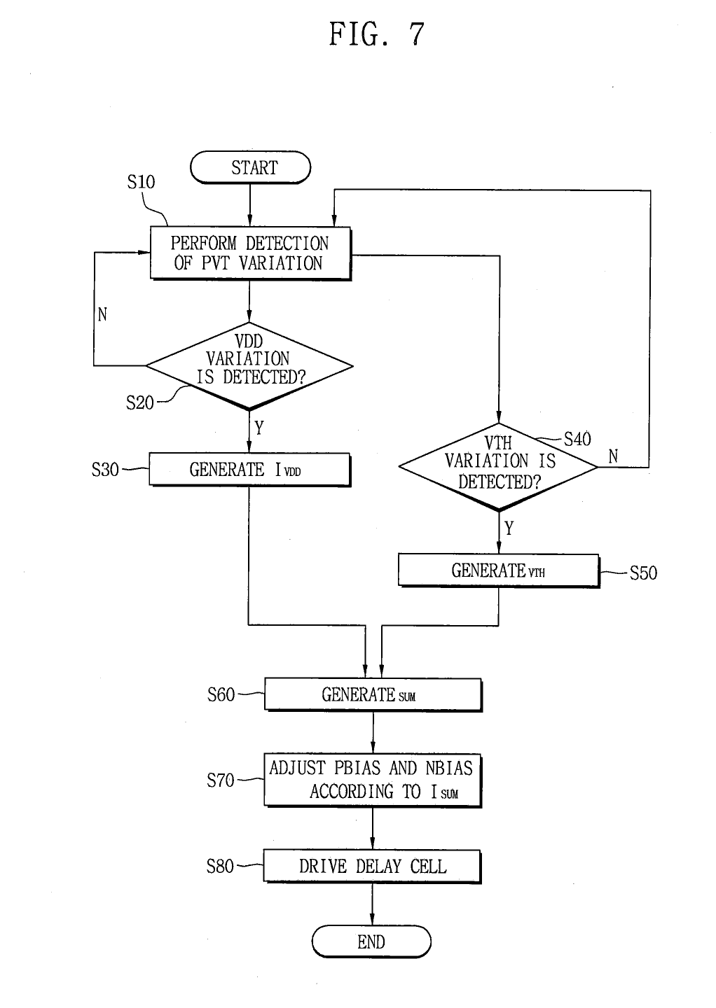

FIG. 7 is a flowchart showing a method of controlling the operation in accordance with the embodiment of the inventive concepts.

Referring to FIGS. 1 to 7, first, the delay control system 100 in accordance with the embodiment of the inventive concepts detects a PVT variation (S10).

As described above, a variation of the power voltage VDD which is an external voltage or a variation of the threshold voltage, which is sensitive to a process, a temperature, and the like, may result in a relatively large impact on the delay cell which adjusts with a fine delay. Thus, the detection of the PVT variation is performed to stably drive the delay cell by detecting and compensating the PVT variation.

Next, whether the VDD voltage is changed or not is detected (S20).

The variation of the VDD voltage may be detected by the voltage detection part 121 (see FIG. 2).

Thus, when the voltage variation is detected (Y in S20), the current adjusting part 123 (see FIG. 2) may supply the VDD compensation current I_{VDD} according to the variation (S30).

For example, when the voltage detection part 121 (see FIG. 2) detects the decrease of the VDD voltage, the current adjusting part 123 (see FIG. 2) may supply the VDD compensation current I_{VDD} increased to more than a preset amount. In contrast, when the voltage detection part 121 (see FIG. 2) detects the increase of the VDD voltage, the current adjusting part 123 (see FIG. 2) may supply the VDD compensation current I_{VDD} decreased to less than the preset amount.

When the VDD voltage variation is not detected (N in S20), the detection operation (S10), whether the VDD voltage is changed or not, is performed again.

The delay control system 100 may detect the PVT variation (S10), and also detect the threshold voltage variation by the threshold voltage compensation unit 130 (see FIG. 3) (S40).

Thus, when a variation of the threshold voltage Vth is detected (Y in S40), the threshold voltage compensation current Iᵥₜₕ may be supplied.

More specifically, when the threshold voltage is decreased according to the temperature variation or the process status, the threshold voltage compensation current Iᵥₜₕ may be decreased and supplied. Further, when the threshold voltage is increased according to the temperature variation or the process status, the threshold voltage compensation current Iᵥₜₕ may be increased and supplied.

In contrast, when the variation of the threshold voltage Vth is not detected (N in S40), the detection operation (S10), whether the VDD voltage is changed or not, is performed again.

Meanwhile, the current summation block 140/140′ (see FIG. 4) may provide the summation current I_{SUM} to include all compensation ranges due to the PVT variation with respect to each generated compensation current by detecting the PVT variation (S60).

In the embodiment of the inventive concepts, although the VDD compensation current increased by M times and the threshold voltage compensation current increased by N times are described in the embodiment of the inventive concepts, it is not limited thereto. The VDD compensation current I_{VDD} and the threshold voltage compensation current Iᵥₜₕ are added to include all the cases generated according to the PVT variation.

Continuing, adjustment of the bias voltage according to the summation current I_{SUM} is performed (S70).

The IV converter 150/150′ (see FIG. 5) may receive the summation current I_{SUM} and optimize the bias voltages required for the delay chain block 170/170′ (see FIG. 1), that is, the PBIAS and NBIAS voltages, according to the amount of the summation current I_{SUM}.

As already described above, when the current receiver 152 receives the summation current I_{SUM} increased to more than a preset value, the IV converter 150 may adjust and provide the PBIAS voltage to have a lower level and the NBIAS voltage to have a higher level. Likewise, when the current receiver 152 receives the summation current I_{SUM} decreased to less than a preset value, the IV converter 150 may adjust and provide the PBIAS voltage to have a higher level and the NBIAS voltage to have a lower level.

Thus, the delay cell may be driven by newly adjusting the bias voltage (S80).

The delay cell 172 (see FIG. 6) may delay and provide the output signals OUT and OUTB with respect to the input signals IN and INB by a predetermined time. In this case, the PBIAS and NBIAS voltages are adjusted in advance to ensure stability of the operation of the delay cell which is sensitive to the PVT, and thus, a variation of the delay time may be reduced even in the PVT variation.

Meanwhile, here, although the detection of the VDD variation (S20) and the detection of the Vth variation (S40) are sequentially described for description of the controlling method, it is possible to change the order thereof. That is, it does not depart from the scope of the inventive concepts when the detection of the Vth variation (S40) is performed first, and then the detection of the VDD variation (S20) is performed.

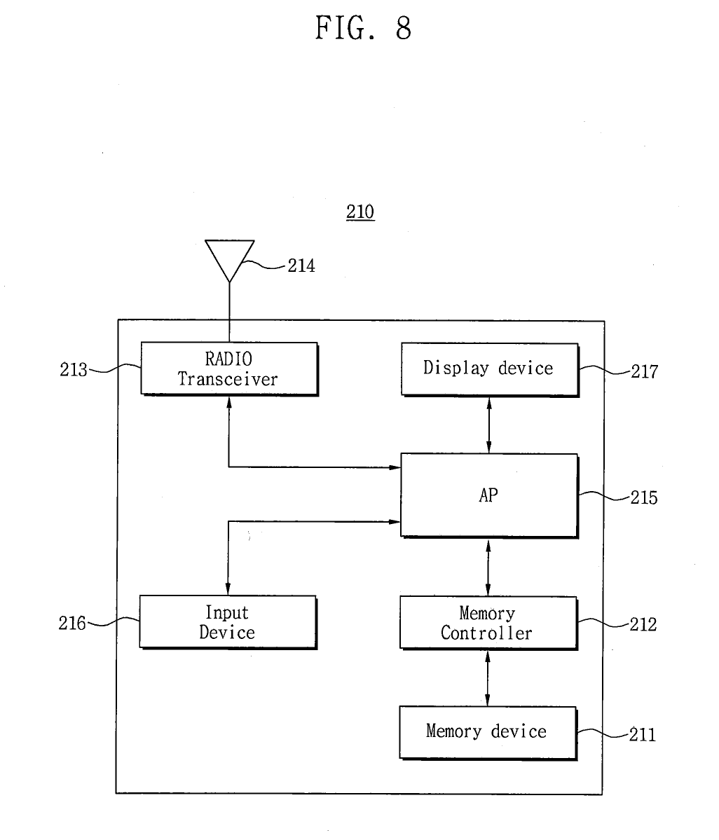

FIG. 8 is a block diagram showing a computer system 210 including the delay control system 100 shown in FIG. 1 in accordance with an embodiment of the inventive concepts.

Referring to FIG. 8, the computer system 210 includes a memory device 211, a memory controller 212 configured to control the memory device 211, a radio transceiver 213, an antenna 214, an application processor (AP) 215, an input device 216, and a display device 217.

The radio transceiver 213 may transmit or receive radio signals through the antenna 214. For example, the radio transceiver 213 may convert a radio signal received through the antenna 214 into a signal which may be processed in the AP 215.

Therefore, the AP 215 may process a signal output from the radio transceiver 213, and transmit a processed signal to the display device 217. Further, the radio transceiver 213 may convert a signal output from the AP 215 into a radio signal, and output the converted radio signal to an external device through the antenna 214.

As the input device 216 is a device in which a control signal for controlling an operation of the AP 215, or data to be processed by the AP 215 may be input, the input device 216 may be implemented as a pointing device, such as a touch pad or a computer mouse, a keypad, or a keyboard.

According to the embodiment of the inventive concepts, the memory controller 212 configured to control an operation of the memory device 211 may be implemented as a part of the AP 215, or as a chip separated from the AP 215.

According to the embodiment of the inventive concepts, the display device 217 may be implemented as the display device including the delay control system 100 shown in FIG. 1. In other embodiments, any of the other blocks of FIG. 8 may include a delay control system 100 shown in FIG. 1.

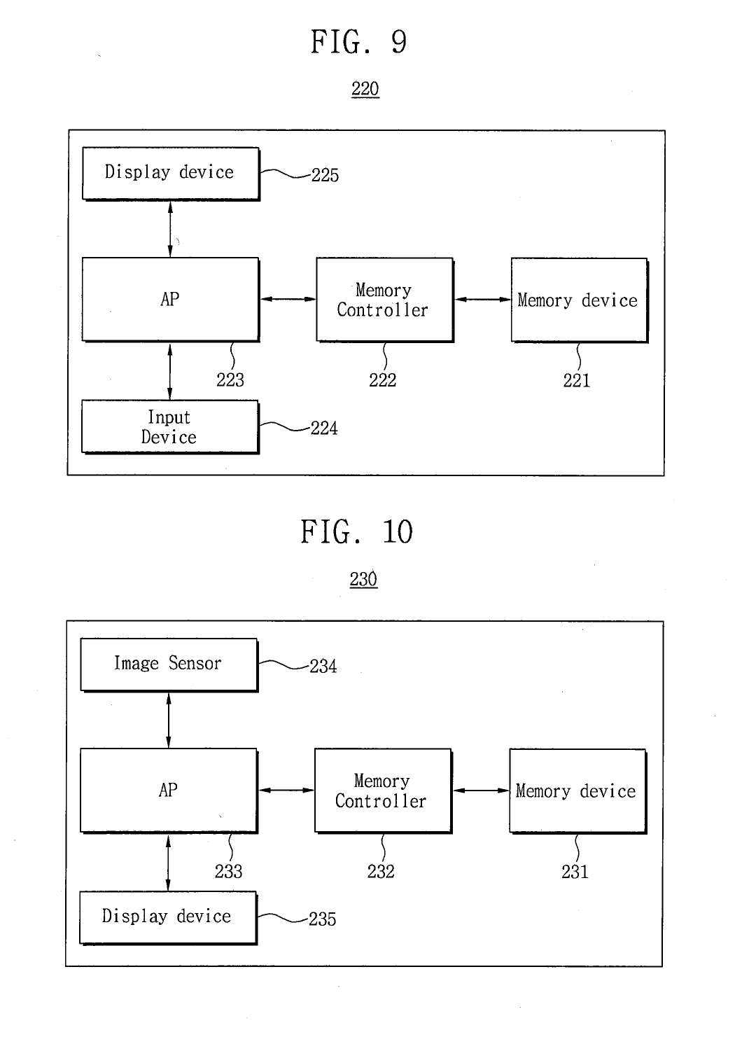

FIG. 9 is a block diagram showing a computer system 220 including the delay control system 100 shown in FIG. 1 in accordance with another embodiment of the inventive concepts.

Referring to FIG. 9, the computer system 220 may be implemented as a personal computer (PC), a network server, a tablet PC, a net-book, an e-reader, a personal digital assistant (PDA), a portable multimedia player (PMP), a MP3 player, or a MP4 player.

The computer system 220 includes a memory device 221, a memory controller 222 configured to control a data processing operation of the memory device 221, an AP 223, an input device 224, and a display device 225.

The AP 223 may display data stored in the memory device 221 through the display device 225 according to data input through the input device 224. For example, the input device 224 may be implemented as a pointing device, such as a touch pad or a computer mouse, a keypad, or a keyboard. The AP 223 may control overall operations of the computer system 220, and control an operation of the memory controller 222.

According to the embodiment, the memory controller 222 configured to control the operation of the memory device 221 may be implemented as a part of the AP 223, or as a chip separated from the AP 223.

According to the embodiment of the inventive concepts, the display device 225 may be implemented as the display device including the delay control system 100 shown in FIG. 1. In other embodiments, any of the other blocks of FIG. 9 may include a delay control system 100 shown in FIG. 1.

FIG. 10 is a block diagram showing a computer system 230 including the delay control system 100 shown in FIG. 1 in accordance with still another embodiment of the inventive concepts.

Referring to FIG. 10, the computer system 230 may be implemented as an image processing device, for example, a digital camera, or a mobile phone, a smart phone, or a tablet, in which the digital camera is mounted.

The computer system 230 includes a memory device 231, a memory controller 232 configured to control a data process operation, for example, a write operation or a read operation of the memory device 231. Further, the computer system 230 includes an AP 233, an image sensor 234, and a display device 235.

The image sensor 234 of the computer system 230 converts an optical image to digital signals, and the converted digital signals are transmitted to the AP 233 or the memory controller 232. The converted digital signals may be displayed on the display device 235, or may be stored in the memory device 231 through the memory controller 232, according to a control of the AP 233.

Further, data stored in the memory device 231 is displayed on the display device 235 according to a control of the AP 233 or the memory controller 232.

According to the embodiment of the inventive concepts, the memory controller 232 configured to control an operation of the memory device 231 may be implemented as a part of the AP 233, or as a chip separated from the AP 233.

According to the embodiment of the inventive concepts, the display device 235 may be implemented as the display device including the delay control system 100 shown in FIG. 1. In other embodiments, any of the other blocks of FIG. 10 may include a delay control system 100 shown in FIG. 1.

The delay control system in accordance with the embodiment of the inventive concepts detects a PVT variation, supplies a compensation current with respect to the variation, adjusts a bias voltage using the compensation current, and thus can provide a delay cell. Thus, since an increase or decrease of the delay time of the delay cell can be controlled and a predetermined delay time is maintained even in the PVT variation, a stable operation of the delay cell can be achieved.

The embodiment of the inventive concepts can be applied to a memory device, and specifically, to a display device and a memory system including the same.

While the inventive concepts have been described with reference to exemplary embodiments, it will be understood by those skilled in the art that various changes and modifications may be made without departing from the spirit and scope of the inventive concepts as defined by the appended claims.

The foregoing is illustrative of embodiments and is not to be construed as limiting thereof. Although a few embodiments have been described, those skilled in the art will readily appreciate that many modifications are possible in embodiments without materially departing from the novel teachings and advantages. Accordingly, all such modifications are intended to be included within the scope of these inventive concepts as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A delay control system, comprising:
a detection compensation block configured to receive a constant current source, detect a process, voltage, and temperature (PVT) variation, and supply a compensation current;
a current summation block configured to receive the compensation current and supply a summation current;
a current-to-voltage (IV) converter configured to receive the summation current and supply bias voltages depending on the amount of the summation current; and
a delay chain block configured to adjust a delay time in response to the bias voltages.

2. The system according to claim 1, wherein the detection compensation block comprises a power supply voltage (VDD) compensation unit and a threshold voltage compensation unit which supply a VDD compensation current and a threshold voltage compensation current, respectively.

3. The system according to claim 2, wherein the VDD compensation unit is configured to receive the constant current source, detect a VDD variation, and supply the VDD compensation current from the constant current source in response to the VDD variation.

4. The system according to claim 3, wherein the VDD compensation unit is configured to supply the VDD compensation current smaller than a value when a detected VDD is higher than a voltage, and the VDD compensation current greater than the value when the detected VDD is lower than the voltage.

5. The system according to claim 2, wherein the threshold voltage compensation unit is configured to receive the constant current source, detect a variation of a threshold voltage, and supply the threshold voltage compensation current from the constant current source in response to the variation of the threshold voltage.

6. The system according to claim 5, wherein the threshold voltage compensation unit is configured to decrease the threshold voltage compensation current to be smaller than a value when the threshold voltage is detected to be lower than a voltage, and to increase the threshold voltage compensation current to be greater than the value when the threshold voltage is detected to be higher than the voltage.

7. The system according to claim 2, wherein the current summation block is configured to sum the VDD compensation current and the threshold voltage compensation current.

8. The system according to claim 1, wherein the IV converter comprises a PBIAS voltage that controls a plurality of PMOS transistors of the delay chain block and an NBIAS voltage that controls a plurality of NMOS transistors of the delay chain block, and
the IV converter is configured to decrease a level of the PBIAS voltage and increase a level of the NBIAS voltage when the summation current is more than a value, and to increase the level of the PBIAS voltage and decrease the level of the NBIAS voltage when the summation current is less than the value.

9. The system according to claim 8, wherein the delay chain block comprises a plurality of delay cells, and a response speed of each delay cell is controlled by the PBIAS voltage and the NBIAS voltage.

10. A delay control system, comprising:
a constant current source that is configured to provide a constant current;
a power supply voltage compensation circuit that is powered by a power supply voltage and is configured to generate a power supply voltage compensation current from the constant current in response to variations of the power supply voltage;
a threshold voltage compensation circuit that is configured to generate a threshold voltage compensation current from the constant current in response to variations in a threshold voltage of a transistor in the threshold voltage compensation circuit;
a current combining circuit that is configured to generate a combined compensation current from the power supply voltage compensation current and the threshold voltage compensation current;
a current-to-voltage converter that is configured to generate a transistor bias voltage from the combined compensation current; and
a delay circuit that includes a plurality of transistors to which the transistor bias voltage is applied and that is configured to delay an input signal by an amount that is based on the transistor bias voltage that is applied to the plurality of transistors.

11. The system according to claim 10 wherein the power supply voltage compensation circuit is configured to generate a first power supply compensation current in response to the power supply voltage being greater than a value and to generate a second power supply compensation current in response to the power supply voltage being less than the value.

12. The system according to claim 10 wherein the threshold voltage compensation circuit is configured to generate a first threshold voltage compensation current in response to the threshold voltage being greater than a value and to generate a second threshold voltage compensation current in response to the threshold voltage being less than the value.

13. The system according to claim 11 wherein the threshold voltage compensation circuit is configured to generate a first threshold voltage compensation current in response to the threshold voltage being greater than a value and to generate a second threshold voltage compensation current in response to the threshold voltage being less than the value.

14. The system according to claim 10 wherein the current combining circuit is configured to sum the power supply voltage compensation current and the threshold voltage compensation current.

15. The system according to claim 13 wherein the current combining circuit is configured to sum the power supply voltage compensation current and the threshold voltage compensation current.

16. The system according to claim 10 wherein the current-to-voltage converter is configured to generate an NMOS transistor bias voltage and a PMOS transistor bias voltage from the combined compensation current.

17. The system according to claim 15 wherein the current-to-voltage converter is configured to generate an NMOS transistor bias voltage and a PMOS transistor bias voltage from the combined compensation current

18. The system according to claim 16 wherein the delay circuit includes a plurality of NMOS and PMOS transistors to which the respective NMOS transistor bias voltage and PMOS transistor bias voltage are applied and wherein the delay circuit is configured to delay the input signal by an amount that is based on the NMOS transistor bias voltage that is applied to the plurality of NMOS transistors and on the PMOS transistor bias voltage that is applied to the plurality of PMOS transistors.

19. The system according to claim 17 wherein the delay circuit includes a plurality of NMOS and PMOS transistors to which the respective NMOS transistor bias voltage and PMOS transistor bias voltage are applied and wherein the delay circuit is configured to delay the input signal by an amount that is based on the NMOS transistor bias voltage that is applied to the plurality of NMOS transistors and on the PMOS transistor bias voltage that is applied to the plurality of PMOS transistors.
